(19) United States
(12) Patent Application Publication
(10) Pub. No.: US 2014/0345671 A1
(43) Pub. Date: Nov. 27, 2014

(54) SOLAR CELL MODULE

(71) Applicant: SANYO ELECTRIC CO., LTD., Osaka (JP)

(72) Inventor: Yukihiro YOSHIMINE, Kobe (JP)

(21) Appl. No.: 14/451,515

(22) Filed: Aug. 5, 2014

Related U.S. Application Data
(63) Continuation of application No. PCT/JP2012/057193, filed on Mar. 21, 2012.

(51) Int. Cl. H01L 31/048; H01L 31/052; H01L 31/042

(52) U.S. Cl. CPC H01L 31/0485; H01L 31/0424; H01L 31/0522
USPC 136/246; 136/251

(57) ABSTRACT

A solar cell module includes: a module main body; a frame body; and a terminal box. The module main body includes a solar cell. The module main body is mounted to the frame body. The terminal box is arranged on a main surface on the side of a rear surface of the module main body. The solar cell is electrically connected to the terminal box. The terminal box is arranged outside an area surrounded by the frame body.

### CROSS REFERENCE TO RELATED APPLICATIONS

This application is a continuation application of International Application No. PCT/JP2012/057193, filed on Mar. 21, 2012, entitled “SOLAR CELL MODULE”, the entire contents of which are incorporated herein by reference.

### BACKGROUND OF THE INVENTION

1. Field of the Invention

This disclosure relates to a solar cell module.

2. Description of Related Art

Patent Document 1 describes a solar cell module including a module main body having solar cells arranged in a sealing material, a frame body mounted to a periphery of the module main body, and a terminal box to which the solar cells are electrically connected. In the solar cell module described in Patent Document 1, the terminal box is arranged in an area surrounded by the frame body.

Patent Document 1: Japanese Patent Application Publication No. 2007-129014

### SUMMARY OF THE INVENTION

There is a demand to further improve durability of a solar cell module. An object of an embodiment of the invention is to provide a solar cell module having improved durability.

A solar cell module according to an aspect of the invention includes a module main body, a frame body, and a terminal box. The module main body includes a solar cell. The module main body is mounted to the frame body. The terminal box is arranged on a main surface on the side of a rear surface of the module main body. The solar cell is electrically connected to the terminal box. The terminal box is arranged outside of an area surrounded by the frame body.

According to the above aspect of the invention, a solar cell module having improved durability can be provided.

### BRIEF DESCRIPTION OF THE DRAWINGS

FIG. 1 is a schematic top view of a solar cell module according to an embodiment of the invention.

FIG. 2 is a schematic cross-sectional view taken along line II-II of FIG. 1.

FIG. 3 is a schematic cross-sectional view taken along line III-III of FIG. 1.

### DETAILED DESCRIPTION OF EMBODIMENTS

Hereinafter, examples of preferred embodiments carrying out the invention are described. It should be noted that the following embodiments are provided just for illustrative purposes. The invention should not be limited at all to the following embodiments.

In the drawings referred to in the embodiments and other parts, components having substantially the same function are referred to with the same reference numeral. In addition, the drawings referred to in the embodiments and other parts are illustrated schematically, and the dimensional ratio and the like of objects depicted in the drawings may be different from those of actual objects in some cases. The dimensional ratio and the like of objects maybe also different among the drawings in some cases. The specific dimensional ratio and the like of objects should be determined with the following description taken into consideration.

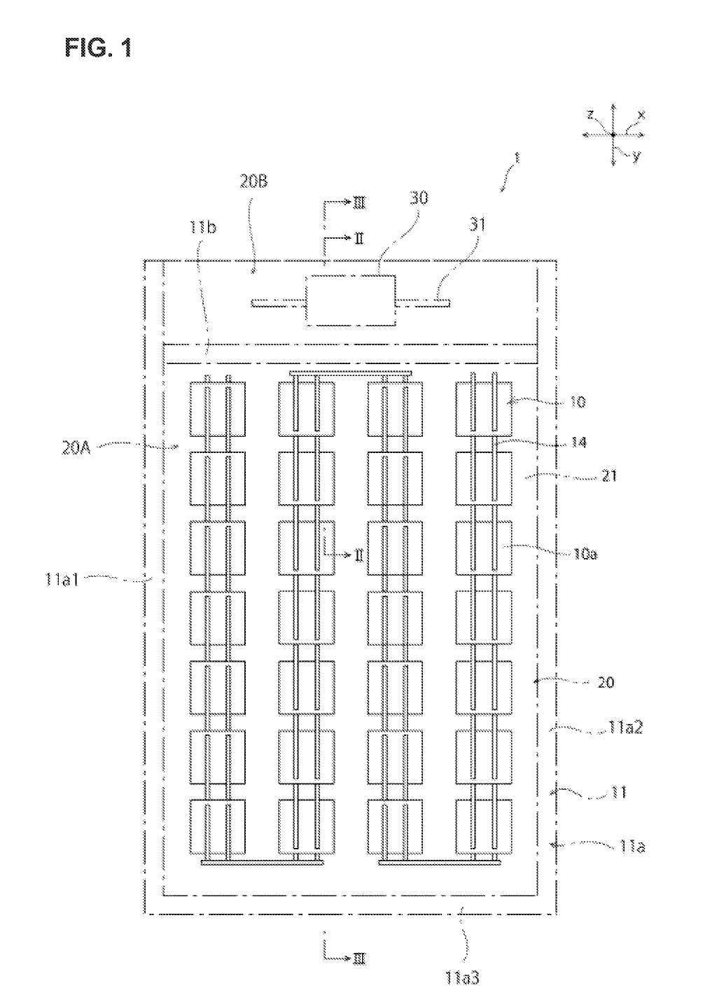

As illustrated in FIG. 1 to FIG. 3, solar cell module 1 includes module main body 20, frame body 11, and terminal box 30.

Module main body 20 has solar cells 10, wiring members 14 electrically connecting solar cells 10, light-receiving surface side protecting member 21, rear surface side protecting member 22, and sealing material 23.

Solar cells 10 are arranged like a matrix having an interval from each other. The type of solar cells 10 is not specifically limited. Solar cells 10 may include, for example, a crystalline-silicon solar cell or a thin-film solar cell and the like. Note that the module main body may have only one solar cell.

Each solar cell 10 has light-receiving surface 10a and rear surface 10b. Here, the “light-receiving surface” refers to a main surface which mainly receives light. While solar cells 10 may generate electric power only when receiving light on light-receiving surfaces 10a, solar cells 10 preferably generate electricity not only when receiving light on light-receiving surfaces 10a but also when receiving light on rear surfaces 10b.

Light-receiving surface side protecting member 21 is arranged on the side of light-receiving surfaces 10a of solar cells 10. Light-receiving surface side protecting member 21 has translucency. Specifically, light-receiving surface side protecting member 21 transmits at least some of light with wavelength which contributes to power generation of solar cells 10. Light-receiving surface side protecting member 21 may comprise a glass plate, a ceramic plate, a resin plate, or the like, for example.

Rear surface side protecting member 22 is arranged on the side of rear surfaces 10b of solar cells 10. Rear surface side protecting member 22 has translucency. Specifically, rear surface side protecting member 22 transmits at least some of light with wavelength which contributes to power generation of solar cells 10. Rear surface side protecting member 22 may comprise a resin sheet, a resin sheet including an inorganic barrier layer having translucency, or the like, for example. The inorganic barrier layer may be a silicon oxide layer, a silicon nitride layer, or the like, for example.

Sealing material 23 is arranged between light-receiving surface side protecting member 21 and rear surface side protecting member 22. Solar cells 10 are sealed by this sealing material 23. Sealing material 23 has translucency. Specifically, sealing material 23 transmits at least some of light with wavelength which contributes to power generation of solar cells 10. Sealing material 23 may comprise cross-linked resin such as ethylene vinyl acetate copolymer and the like, non-cross-linked resin such as polyolefin and the like, or the like. Sealing material 23 contains no pigment or dye.

As described above, light-receiving surface side protecting member 21, rear surface side protecting member 22 and sealing material 23 respectively have translucency. Thus, some of light which enters an area of module main body 20 where no solar cells 10 are provided passes through module main body 20.

Frame body 11 is mounted to module main body 20. Frame body 11 has first portion 11a and second portion 11b. First portion 11a is provided around module main body 20. A periphery of module main body 20 is inserted in first portion 11a and fixed thereto. First portion 11a has portion 11a1 covering a first end face of rectangular module main body 20, portion 11a2 covering a second end face opposed to the first end face, and portion 11a3 covering a third end face connecting the first end face and the second end face.

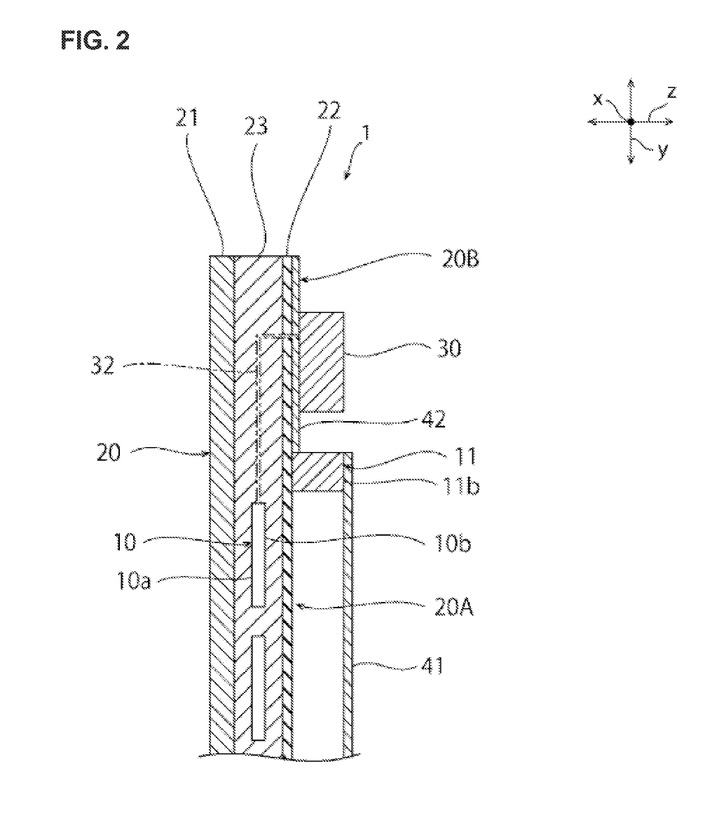

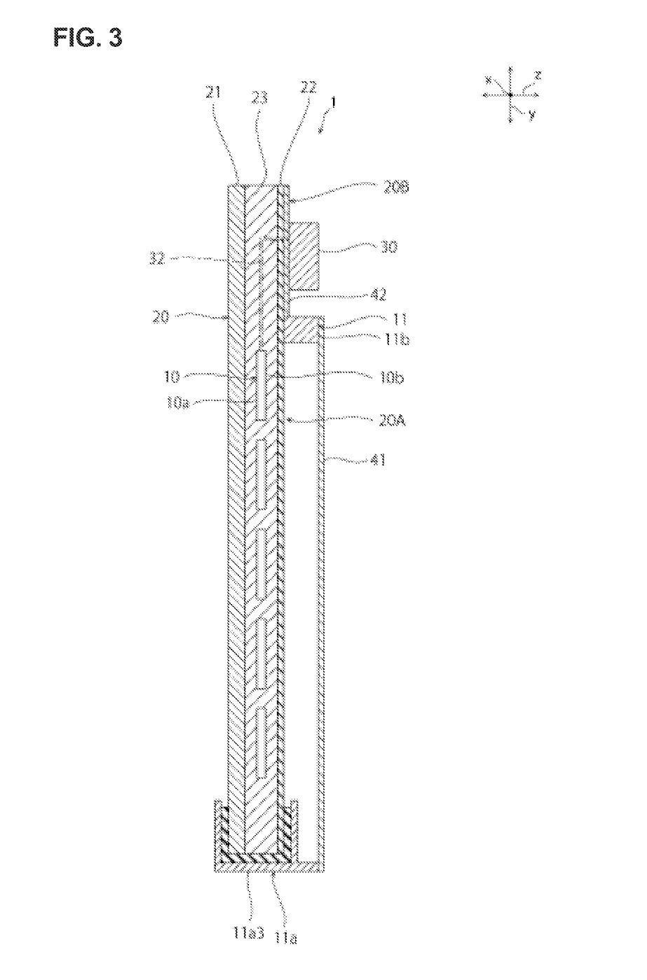

As illustrated in FIG. 1, second portion 11b is connected to portion 11a1 and portion 11a2. As illustrated in FIG. 2 and FIG. 3, second portion 11b is arranged on a main surface on the side of rear surface 10b of module main body 20. Therefore, the area where module main body 20 is provided contains area 20A surrounded by frame body 11 and area 20B which lies outside of area 20A. One or more solar cells 10 may or may not be provided in area 20B. In the embodiment, solar cells 10 are not provided in area 20B.

Terminal box 30 is arranged on the main surface on the side of rear surface 10b of module main body 20. Solar cells 10 are electrically connected to terminal box 30. Terminal box 30 is arranged in area 20B. Cable 31 as illustrated in FIG. 1 is electrically connected to terminal box 30. Cable 31 has a coating layer made of resin.

As illustrated in FIG. 2 and FIG. 3, wiring 32 connecting terminal box 30 and solar cells 10 is provided within module main body 20. Specifically, in area 20B, wiring 32 drawn from solar cells 10 is drawn out of module main body 20 by way of sealing material 23 and rear surface side protecting member 22. In area 20A, wiring 32 is not positioned on the main surface on the side of rear surface 10b of module main body 20. Note that in FIG. 2 and FIG. 3, wiring 32 is schematically illustrated. An actual drawing route of wiring 32 differs from the drawing route of wiring 32 as illustrated in FIG. 2 and FIG. 3.

Reflecting member 41 is arranged on the side of rear surface 10b of module main body 20. Reflecting member 41 is provided substantially all over area 20A. Reflecting member 41 is spaced from module main body 20. Reflecting member 41 reflects light from the side of light-receiving surface 10a.

Reflecting member 42 is arranged between module main body 20 and terminal box 30. Reflecting member 42 is provided substantially all over area 20B. Reflecting member 42 reflects light from the side of module main body 20.

Incidentally, in the case of a solar cell module having an area surrounded by a frame body, temperature of the area surrounded by the frame body easily rises. Thus, temperature of a terminal box or a cable connected to the terminal box in the area surrounded by the frame body easily rises. Therefore, the terminal box or the cable is susceptible to damage.

In contrast to this, in solar cell module 1, terminal box 30 is arranged in area 20B which is outside of area 20A surrounded by frame body 11. Since this area 20B is not surrounded by frame body 11, it is aerated. Thus, heat does not easily persist in area 20B. Accordingly, temperature of terminal box 30 or cable 31 which is arranged in area 20B does not easily rise. Hence, solar cell module 1 having improved durability can be achieved.

In solar cell module 1, wiring 32 electrically connecting solar cells 10 with terminal box 30 is arranged in module main body 20, and not positioned on the side of rear surface 10b of module main body 20 in area 20A temperature of which easily goes high. Thus, wiring 32 is not easily damaged. Therefore, solar cell module 1 having improved durability can be achieved.

In solar cell module 1, reflecting member 41 is provided on the side of the rear surface of module main body 20. Light transmitting between solar cells 10 is reflected by this reflecting member 41, and some of the light enters solar cells 10. Thus, the efficiency of receiving light of solar cells 10 can be improved.

For example, it is also possible to provide a reflecting layer on a rear surface side protecting member. In such a case, however, a distance between the reflecting layer and solar cells is short. Thus, light reflected by the reflecting layer does not easily enter the solar cells. In particular, the light reflected by the reflecting layer does not easily enter an effective area of the solar cells. In contrast to this, in solar cell module 1, reflecting member 41 is arranged on the side of the rear surface of module main body 20. Thus, a distance between reflecting member 41 and solar cells 10 can be made long. Therefore, light reflected by reflecting member 41 easily enters an effective area of the solar cells. Accordingly, improved output characteristics can be achieved. From a standpoint of achieving further improved output characteristics, it is preferable that reflecting member 41 is spaced from module main body 20.

Incidentally, it is possible to arrange solar cells also in area 20B, for example. In this case, however, a distance between a reflecting member provided on the side of the rear surface of the solar cells and the solar cells differs in area 20A and in area 20B. Thus, output of the solar cells positioned in area 20B differs from output of the solar cells positioned in area 20A. Therefore, like solar cell module 1, it is preferable not to provide solar cells 10 in area 20B.

In solar cell module 1, reflecting member 42 is arranged between module main body 20 and terminal box 30. For this reason, light does not easily enter terminal box 30. Thus, temperature of terminal box 30 does not easily rise and terminal box 30 is not easily damaged. Therefore, durability of solar cell module 1 is further improved. From a standpoint of more effectively controlling temperature rise of terminal box 30, it is preferable to provide reflecting member 42 all over area 20B.

In addition, provision of reflecting member 42 makes it difficult to visibly recognize terminal box 30 from the side of the light-receiving surface. Thus, appearance of solar cell module 1 can be improved.

In solar cell module 1, while single rear surface side protecting member 22 is provided, extending across area 20A and area 20B, separate rear surface side protecting members may be provided in area 20A and area 20B. In that case, it is preferable that the rear surface side protecting member positioned in area 20A has higher heat resistance than the rear surface side protecting member positioned in area 20B.

Although solar cell module 1 has been described with reference to the example in which reflecting member 42 is provided on rear surface side protecting member 22, no special limitation is imposed on a location in area 20B where reflecting member 42 is to be placed. Reflecting member 42 may be arranged between light-receiving surface side protecting member 21 positioned in area 20B and sealing material 23, for example.

### EXPLANATION OF THE REFERENCE NUMERALS

1 solar cell module
10 solar cell
10a light receiving surface
10b rear surface
11 frame body
14 wiring member
20 module main body
21 light-receiving surface side protecting member
22 rear surface side protecting member
23 sealing material
30 terminal box
31 cable
32 wiring
41, 42 reflecting member

1. A solar cell module, comprising:
a module main body including a solar cell;
a frame body to which the module main body is mounted; and
a terminal box which is arranged on a main surface on the side of a rear surface of the module main body and to which the solar cell is electrically connected, wherein
the terminal box is arranged outside an area surrounded by the frame body.

2. The solar cell module according to claim 1, further comprising:
a wiring electrically connecting the terminal box and the solar cell, wherein
the wiring is provided in the module main body.

3. The solar cell module according to claim 1, wherein
the module main body includes:
a light-receiving surface side protecting member arranged on the side of light-receiving surfaces of the solar cell;
a rear surface side protecting member arranged on the side of rear surfaces of the solar cell; and
a sealing material arranged between the light-receiving surface side protecting member and the rear surface side protecting member and sealing the solar cell, wherein
each of the light-receiving surface side protecting member, the rear surface side protecting member, and the sealing material has translucency.

4. The solar cell module according to claim 3, further comprising:
a reflecting member arranged on the side of the rear surface of the module main body.

5. The solar cell module according to claim 4, wherein
the reflecting member is spaced from the module main body.

6. The solar cell module according to claim 1, further comprising:
a reflecting member arranged between the module main body and the terminal box.
